(19) United States
(12) Patent Application Publication
(10) Pub. No.: US 2012/0049265 A1
(43) Pub. Date: Mar. 1, 2012

(54) SEMICONDUCTOR DEVICES HAVING DIELECTRIC GAPS

(75) Inventors: Hwan Bae Yoo, Osan-si (KR); Juneui Song, Yongin-si (KR); Hyunchul Shin, Seoul (KR); Da-Hoon Yu, Seoul (KR)

(73) Assignee: Samsung Electronics Co., Ltd.

(21) Appl. No.: 13/212,426

(22) Filed: Aug. 18, 2011

(30) Foreign Application Priority Data
Aug. 30, 2010 (KR) 10-2010-0084220

(51) Int. Cl. H01L 29/788

(52) U.S. Cl. 257/315; 257/E29.3

(57) ABSTRACT

A method of fabricating a semiconductor device, can be provided by forming first and second gate patterns on a semiconductor substrate. First and second insulating spacers can be formed on first and second sidewalls of the first and second gate patterns, respectively. A capping insulation can be formed on an entire surface of the semiconductor substrate including on the first and second insulating spacers. The first insulating spacers can be removed to form an air gap between the first and second gate patterns. Related devices are also disclosed.

### CROSS-REFERENCE TO RELATED APPLICATIONS

This U.S. non-provisional patent application claims priority under 35 U.S.C. §119 of Korean Patent Application No. 10-2010-0084220, filed on Aug. 30, 2010, the entire contents of which are hereby incorporated by reference.

### BACKGROUND

The present disclosure herein relates to the field of electronics, and more particularly, to semiconductor devices.

Semiconductor memory devices for storing data may be classified into volatile memory devices and nonvolatile memory devices. The nonvolatile memory devices are widely used for computers, memory cards, or mobile telecommunication systems.

The nonvolatile memory devices include a plurality of nonvolatile memory cells. Each of the nonvolatile memory cells includes a tunnel insulation layer, a floating gate, an inter-gate insulation layer, and a control gate electrode, which are sequentially stacked on a semiconductor substrate. Regions between the nonvolatile memory cells may be filled with a dielectric layer. For example, regions between the adjacent floating gates may be filled with a dielectric layer such as a silicon oxide layer and/or a silicon nitride layer.

Parasitic capacitance within the a non-volatile memory device may increase as the distance between the floating gates decreases. That is, as the integration density of the nonvolatile memory devices is increased, a parasitic coupling capacitance between the floating gates may also be increased.

When a first memory cell among the plurality of nonvolatile memory cells is selectively programmed, electrons are injected into the floating gate of the first memory cell. The electric potential of the floating gate in a second memory cell adjacent to the first memory cell may change due to parasitic coupling capacitance. That is, a threshold voltage of the second memory cell may be changed. Accordingly, a read error may occur in an operating mode for selectively reading data stored in the second memory cell. Especially, if the integration density of the nonvolatile memory devices is increased, possibility that the read errors occur may be further increased.

### SUMMARY

Embodiments according to the inventive concept can provide methods of forming semiconductor devices including dielectric gaps and related devices. Pursuant to these embodiments, a method of fabricating a semiconductor device, can be provided by forming first and second gate patterns on a semiconductor substrate. First and second insulating spacers can be formed on first and second sidewalls of the first and second gate patterns, respectively. A capping insulation can be formed on an entire surface of the semiconductor substrate including on the first and second insulating spacers. The first insulating spacers can be removed to form an air gap between the first and second gate patterns.

In some embodiments according to the inventive concept, the method can further include forming a common source line in the semiconductor substrate between the first and second gate patterns prior to formation of the first and second insulating spacers and forming drain regions in the semiconductor substrate outside the first and second gate patterns, where the air gap is formed on the common source line.

In some embodiments according to the inventive concept, the method can further include forming a bit line on the capping insulation layer that penetrates the capping insulation layer to electrically connect to the drain regions. In some embodiments according to the inventive concept, forming the first and second gate patterns can include forming a tunnel insulation layer, a floating gate, an inter-gate insulation layer and a control gate electrode sequentially stacked.

In some embodiments according to the inventive concept, removing the first insulating spacers to form an air gap can be provided by removing the first insulating spacers so that at least a portion of the air gap is located between a floating gates of the first gate pattern and the a floating gate of the second gate pattern. In some embodiments according to the inventive concept, removing the first insulating spacers to form an air gap further can maintain the second insulating spacer and the capping insulating layer above the air gap.

In some embodiments according to the inventive concept, a semiconductor device can include a device isolation layer on a semiconductor substrate that defines a plurality of main active regions. First and second gate patterns cross over the main active regions and the device isolation layer therebetween. A common source line in the semiconductor substrate can be between the first and second gate patterns. A capping insulation layer can cover an air gap between the first and second gate patterns. A plurality of first drain regions can be located in the main active regions immediately adjacent to the first gate pattern and located distal from the second gate pattern, respectively. A plurality of second drain regions can be located in the main active regions immediately adjacent to the second gate pattern and located distal from the first gate pattern, respectively.

In some embodiments according to the inventive concept, a non-volatile semiconductor memory device can include immediately adjacent floating gates that are spaced apart by a gap on a semiconductor substrate in a main memory region of the device. A capping insulating layer can be located above the substrate, and bridge the gap. A common source line can be located in the semiconductor substrate and shared by the immediately adjacent floating gates.

In some embodiments according to the inventive concept, the capping insulating layer extends over the immediately adjacent floating gates and onto sidewalls thereof in the main memory region of the device over immediately adjacent drain regions in the semiconductor substrate. In some embodiments according to the inventive concept, the device can further include a bit line in the main memory region of the device that penetrates the capping insulating layer to electrically connect to one of the immediately adjacent drain regions.

In some embodiments according to the inventive concept, the gap can be a first distance, and device can further include a dummy floating gate, in a dummy region of the device, that is spaced apart from a closest one of the immediately adjacent floating gates by a second distance that is greater than the first distance. In some embodiments according to the inventive concept, the second distance is greater than the first distance.

In some embodiments according to the inventive concept, the second distance between the dummy floating gate and the closest one of the immediately adjacent floating gates is free of the gap.

### BRIEF DESCRIPTION OF THE DRAWINGS

FIG. 1 is a plan view illustrating a portion of a cell array region of NOR-type nonvolatile memory devices according to embodiments of the inventive concept.

FIGS. 2A through 7A are sectional views taken along the line I-I′ of FIG. 1 to illustrate methods of fabricating NOR-type nonvolatile memory devices according to an embodiments of the inventive concept.

FIGS. 2B through 7B are sectional views taken along the line II-II′ of FIG. 1 to illustrate methods of fabricating NOR-type nonvolatile memory device according to an embodiments of the inventive concept.

FIGS. 2C through 7C are sectional views taken along the line of FIG. 1 to illustrate methods of fabricating NOR-type nonvolatile memory devices according to embodiments of the inventive concept.

### DETAILED DESCRIPTION OF THE EMBODIMENTS ACCORDING TO THE INVENTIVE CONCEPT

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout.

In the following description, the technical terms are used only for explaining specific embodiments while not limiting the inventive concept. As used herein, the singular forms “a”, “an” and “the” are intended to include the plural forms as well, unless the context clearly indicates otherwise. It will be further understood that the terms “include”, “comprise”, “including” and/or “comprising” when used in this specification, specifies the presence of stated features, regions, integers, steps, operations, elements and/or components but do not preclude the presence or addition of one or more other features, regions, integers, steps, operations, elements, components and/or groups thereof.

Additionally, the embodiments in the detailed description will be described with sectional views as ideal exemplary views of the inventive concept. In the drawings, the dimensions of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate a specific shape of a semiconductor device. Thus, this should not be construed as limited to the scope of the inventive concept.

Although “air gaps” are described herein in embodiments according to the inventive concept, any gap may be used according to embodiments of the inventive concept. A gap may be defined, for example, as any void or cavity, and may be a gap filled with air (e.g., an air gap), a gap filled with an inert gas or gases (e.g., an inert gas gap), a gap defining a vacuum (e.g., a vacuum gap), etc. As appreciated by the present inventive entity, the gap may help reduce parasitic capacitance due to coupling between immediately adjacent gate structures by reducing dielectric material therebetween.

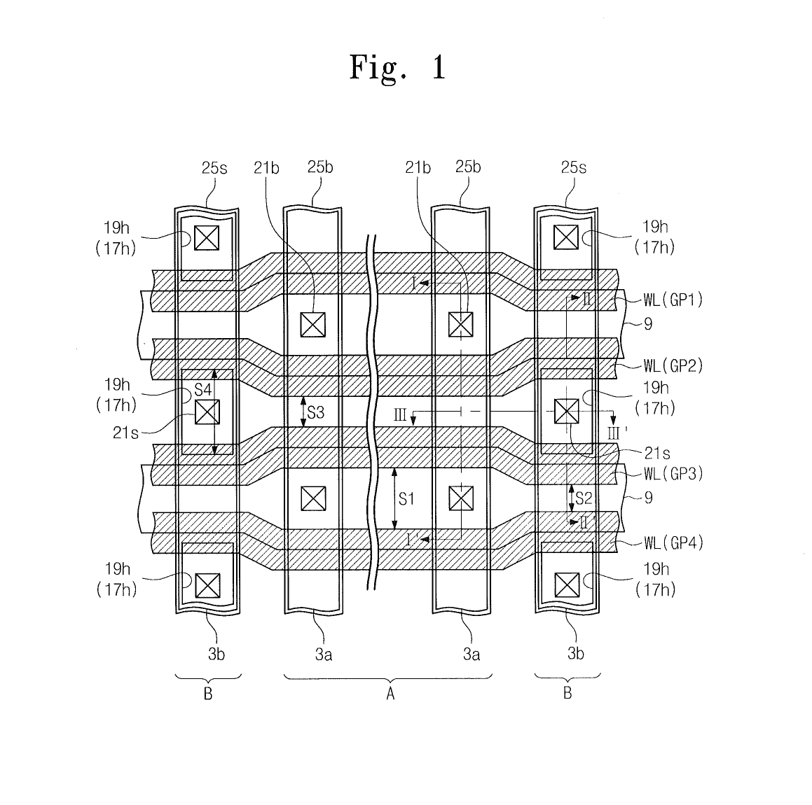

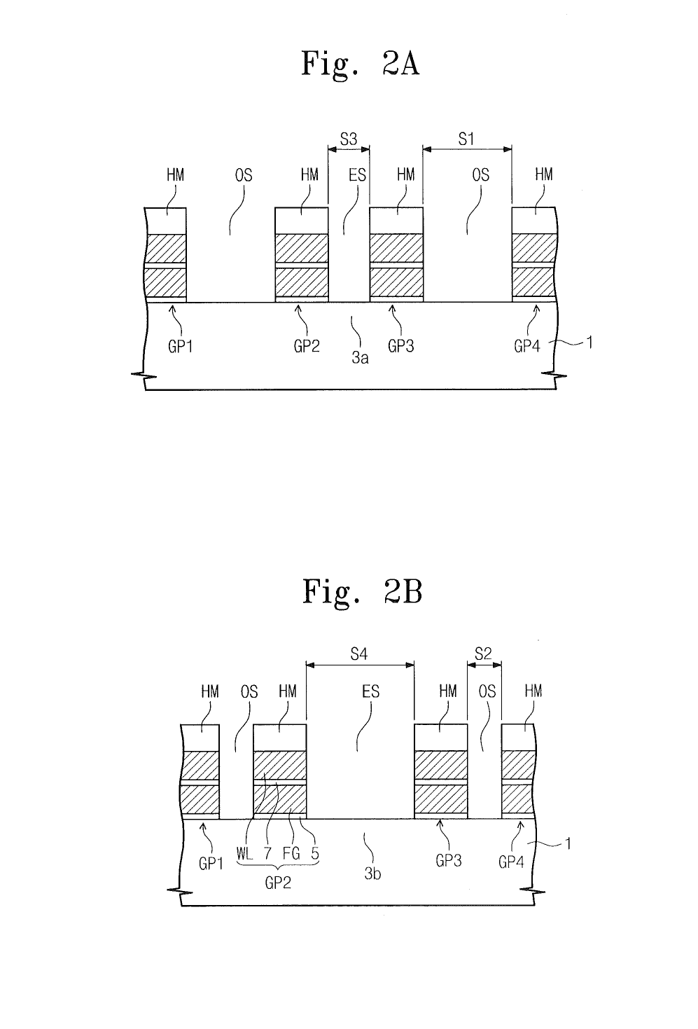

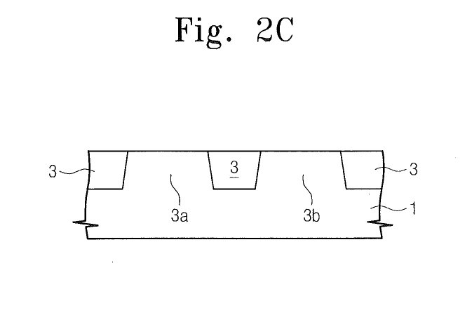

FIG. 1 is a plan view illustrating a portion of a cell array region of NOR-type nonvolatile memory devices according to embodiments of the inventive concept. FIGS. 2A through 7A are sectional views taken along the line I-I′ of FIG. 1 to illustrate methods of fabricating NOR-type nonvolatile memory device according to embodiments of the inventive concept. FIGS. 2B through 7B are sectional views taken along the line II-II′ of FIG. 1 to illustrate methods of fabricating NOR-type nonvolatile memory devices according to embodiments of the inventive concept. FIGS. 2C through 7C are sectional views taken along the line III-III′ of FIG. 1 to illustrate methods of fabricating NOR-type nonvolatile memory devices according to embodiments of the inventive concept. In the drawing of FIG. 1, a reference character “A” represents a main cell region and a reference character “B” represents a dummy cell region.

Referring to FIGS. 1, 2A, 2B, and 2C, a device isolation layer 3 is formed on a semiconductor substrate 1 to define main active regions 3a and dummy active regions 3b. The device isolation layer 3 may be formed using a trench isolation technique. The main active regions 3a are formed in the main cell region A and the dummy active regions 3b are formed in the dummy cell regions B located at both sides of the main cell region A.

A plurality of gate patterns, for example, first to fourth gate patterns GP1, GP2, GP3, and GP4 may be formed to cross over the main active regions 3a and the dummy active regions 3b. In FIG. 1, only a portion of the cell array region is shown. Accordingly, the number of the gate patterns may be greater than 4.

Hard masks HM may be formed on the gate patterns GP1, GP2, GP3, and GP4. That is, the gate patterns GP1, GP2, GP3, and GP4 may be formed using the hard masks HM as an etching mask. The hard masks HM may be formed of a silicon oxide layer using a chemical vapor deposition (CVD) technique.

Each of the gate patterns GP1, GP2, GP3, and GP4 may include a word line WL crossing over the main active regions 3a and the dummy active regions 3b, floating gates FG disposed at intersection points between the word line WL and the active regions 3a and 3b, a tunnel insulation layer 5 between the floating gates FG and the active regions 3a and 3b, and an inter-gate insulation layer 7 between the word line WL and the floating gates FG. The word lines WL correspond to control gate electrodes.

Spaces between the gate patterns GP1, GP2, GP3 and GP4 may include odd-numbered spaces OS and even-numbered spaces ES between the odd-numbered spaces OS, as shown in FIGS. 2A, 2B, and 2C.

A first interval S1 between the third and fourth gate patterns GP3 and GP4 in the main cell region A may be greater than a second interval S2 between the third and fourth gate patterns GP3 and GP4 in the dummy cell region B, as shown in FIGS. 2A and 2B. Additionally, a third interval S3 between the second and third gate patterns GP2 and GP3 in the main cell region A may be less than a fourth interval S4 between the second and third gate patterns GP2 and GP3 in the dummy cell region B. That is, the first interval S1 corresponding to the width of the odd-numbered spaces OS in the main cell region A may be greater than the second interval S2 corresponding to the width of the odd-numbered spaces OS in the dummy cell region B, and the third interval S3 corresponding to the width of the even-numbered spaces ES in the main cell region A may be less than the fourth interval S4 corresponding to the width of the even-numbered spaces ES in the dummy cell region B.

Furthermore, the third interval S3 corresponding to the width of the even-numbered spaces ES in the main cell region A may be less than the first interval S1 corresponding to the width of the odd-numbered spaces OS in the main cell region A, and the fourth interval S4 corresponding to the width of the even-numbered spaces ES in the dummy cell region B may be greater than the second interval S2 corresponding to the odd-numbered spaces OS in the dummy cell region B.

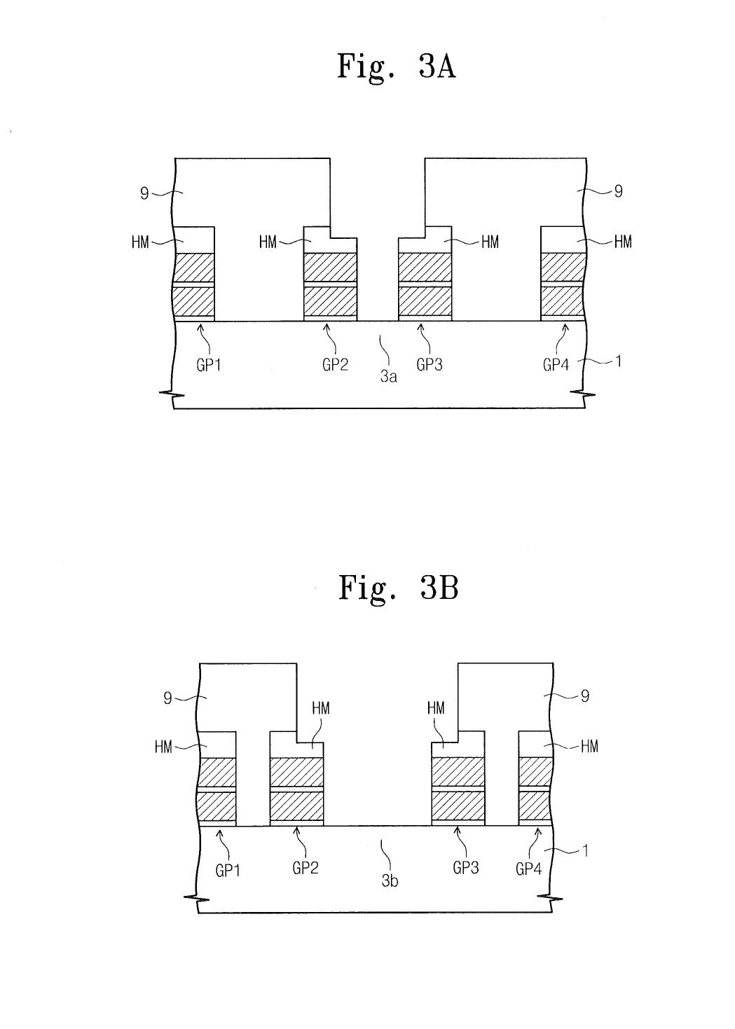

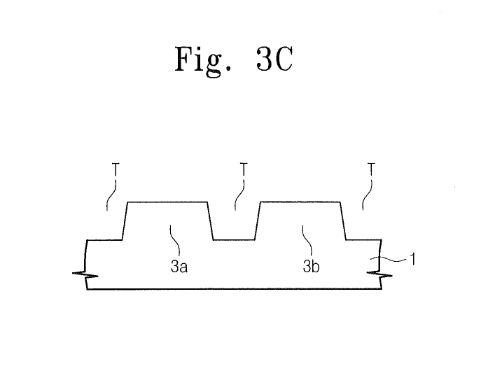

Referring to FIGS. 1, 3A, 3B, and 3C, a first mask pattern 9 is formed on a substrate having the gate patterns GP1, GP2, GP3, and GP4. The first mask pattern 9 may be formed to cover the odd-numbered spaces OS and expose the even-numbered spaces ES. As a result, the device isolation layer 3 below the even-numbered spaces ES may also be exposed.

In one embodiment, the device isolation layer 3 exposed by the first mask pattern 9 may be selectively removed to expose sidewalls and bottom surfaces of trench regions T in the even-numbered spaces ES.

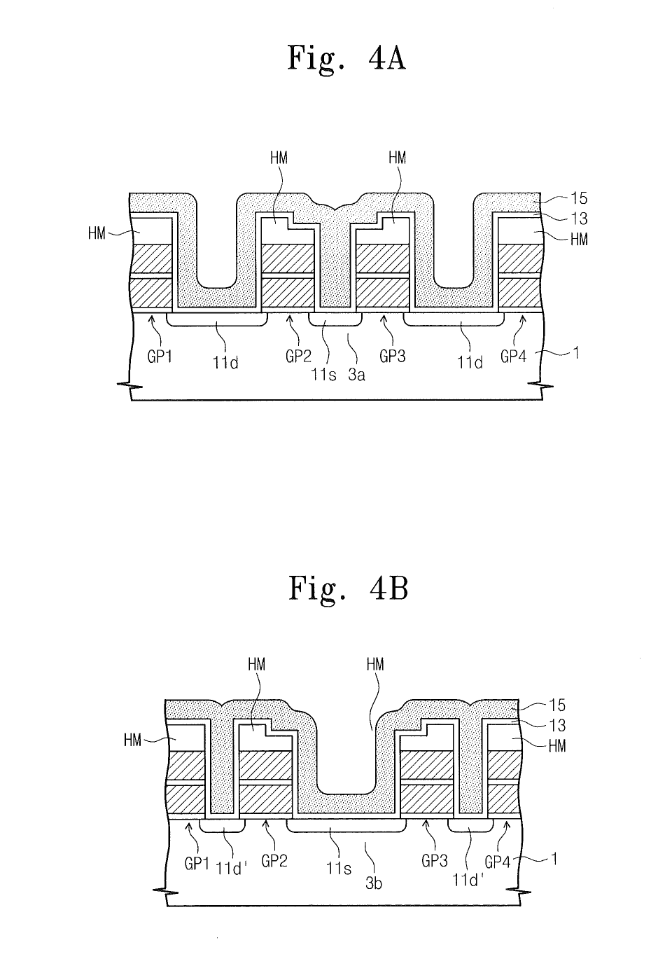

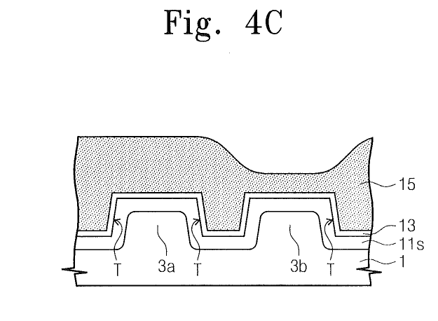

Referring to FIGS. 1, 4A, 4B, and 4C, the first mask pattern 9 is removed, and impurity ions are injected into the semiconductor substrate 1 using the gate patterns GP1, GP2, GP3, and GP4 and the device isolation layer 3 as ion implantation masks. As a result, line-shaped impurity regions, i.e., common source lines 11s, may be formed below the even-numbered spaces ES, and drain regions may be formed in the active regions 3a and 3b below the odd-numbered spaces OS. The drain regions may be formed to include main drain regions 11d in the main active regions 3a and dummy drain regions 11d′ in the dummy active regions 3b.

The common source lines 11s and the drain regions 11d and 11d′ may be formed to have a different conductive type from the semiconductor substrate 1. For example, when the semiconductor substrate 1 is doped with P-type impurity ions, the common source lines 11s and the drain regions 11d and 11d′ may be N-type impurity regions. In another embodiment, the common source lines 11s may be formed prior to removal of the first mask pattern 9.

A first insulation layer 13 and a second insulation layer 15 may be sequentially formed on the substrate having the common source lines 11s and the drain regions 11d and 11d′. The second insulation layer 15 may be formed of a material layer having an etch selectivity with respect to the first insulation layer 13. For example, the first and second insulation layers 13 and 15 may be formed of a silicon oxide layer and a silicon nitride layer, respectively. In some embodiments according to the inventive concept, the first insulation layer 13 may be formed of a thermal oxide layer or a CVD oxide layer.

The second insulation layer 15 may be formed to fill the even-numbered spaces ES having the third interval S3. For example, the second insulation layer 15 may be formed to a thickness (for example, on an upper surface of the first insulating layer 13) corresponding to at least about ½ of the third interval S3, so that the second insulating layer 15 may fill the even spaces ES in the main region and the odd spaces OS in the dummy region.

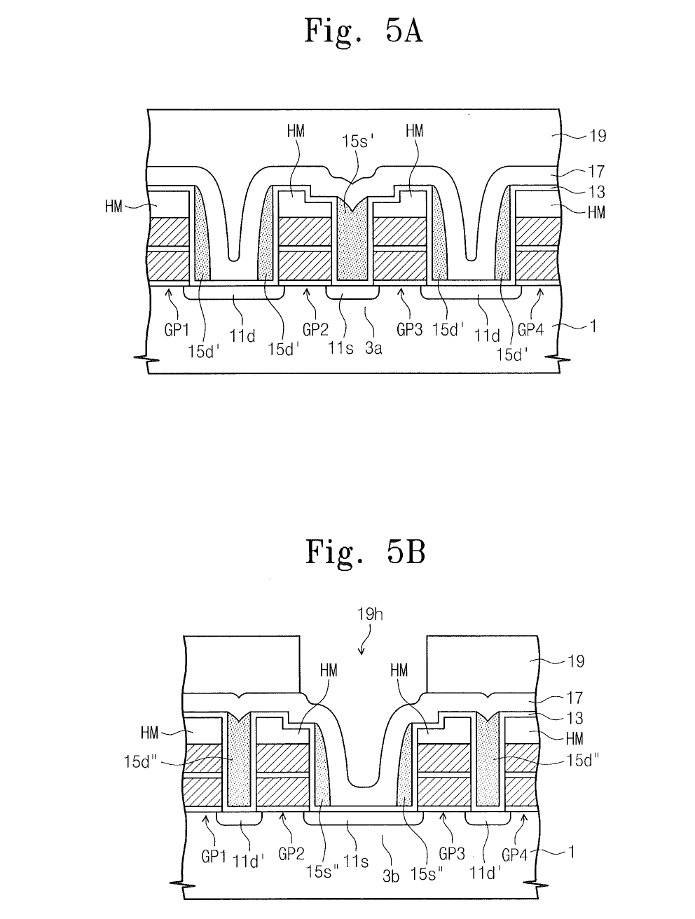

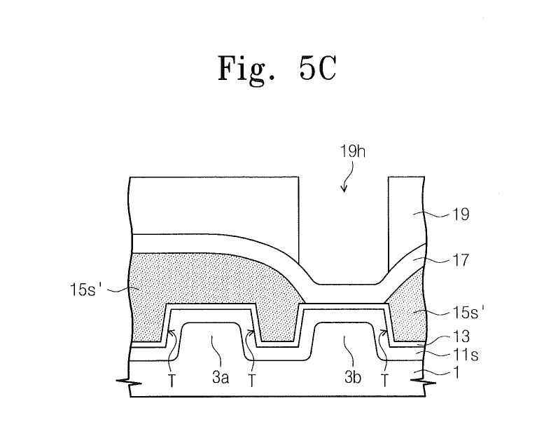

Referring to FIGS. 1, 5A, 5B, and 5C, the second insulation layer 15 may be anisotropically etched to form insulating spacers on the sidewall of the gate patterns GP1, GP2, GP3, and GP4. The insulating spacers may include first insulating spacers in the even-numbered spaces ES and second insulating spacers in the odd-numbered spaces OS.

The first insulating spacers may be formed to include main source-side spacers 15s′ in the main cell region A and dummy source-side spacers 15s″ in the dummy cell region B. Similarly, the second insulating spacers may be formed to include main drain-side spacers 15d′ in the main cell region A and dummy drain-side spacers 15d″ in the dummy cell region B.

The main source-side spacers 15s′ may be formed to fill the even-numbered spaces ES in the main cell region A and the main drain-side spacers 15d′ may be formed to expose the first insulation layer 13 on the main drain regions 11d. Furthermore, the dummy source-side spacers 15s″ may be formed to expose the first insulation layer 13 on the common source line 11s in the dummy active regions 3b and the dummy drain-side spacers 15d″ may be formed to fill the odd-numbered spaces OS in the dummy cell region B. In each of the even-numbered spaces ES, the main source-side spacer 15s′ is connected to the dummy source-side spacer 15s″.

A capping insulation layer 17 may be formed on an entire surface of the substrate having the first and second insulating spacers 15s, 15s″, 15d′, and 15d″. The capping insulating layer 17 may be formed of a material layer having an etch selectivity with respect to the insulating spacers 15s′, 15s″, 15d′, and 15d″. For example, when the insulating spacers 15s′, 15s″, 15d′, and 15d″ are formed of a silicon nitride layer, the capping insulation layer 17 may be formed of a silicon oxide layer.

A second mask pattern 19 is formed on the capping insulation layer 17. The second mask pattern 19 may be formed to include openings 19h on the common source lines 11s in the dummy active regions 3b. That is, the openings 19h expose the capping insulation layer 17 on the common source lines 11s in the dummy active regions 3b.

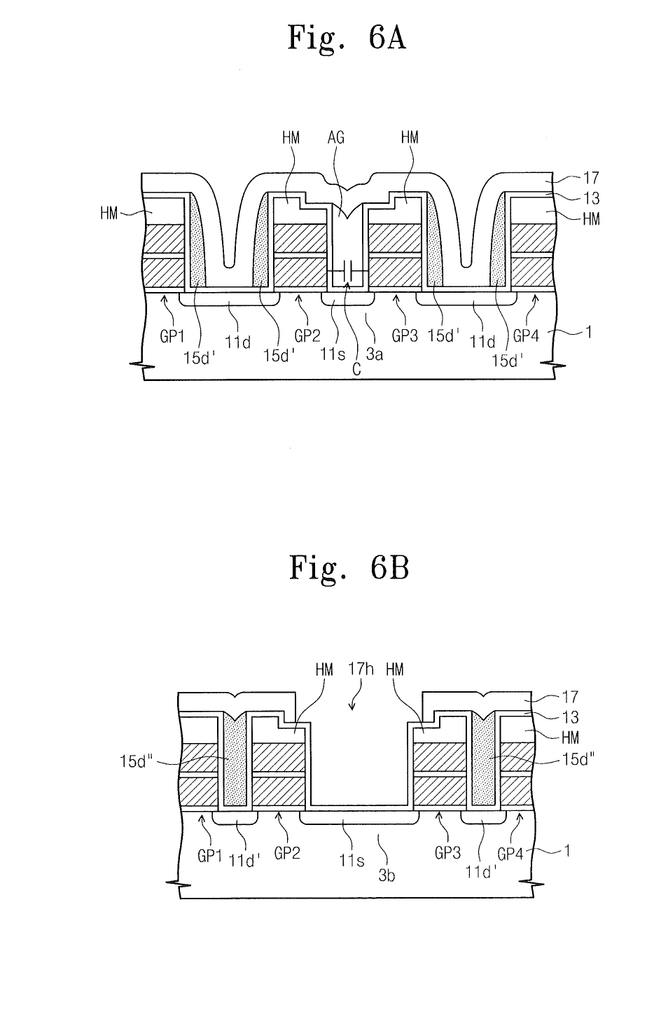

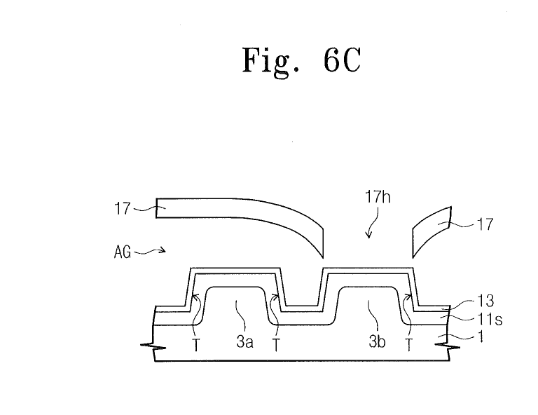

Referring to FIGS. 1, 6A, 6B, and 6C, the exposed capping insulation layer 17 is etched using the second mask pattern 19 shown in FIGS. 5A, 5B, and 5C as an etching mask. As a result, openings 17h exposing the dummy source-side spacers 15s″ in the dummy active regions 3b may be formed in the capping insulation layer 17.

The exposed dummy source-side spacers 15s″ may be selectively removed using an isotropic etching process. During the isotropic etching process, the main source-side spacers 15s′ connected to the exposed dummy source-side spacers 15s″ may also be selectively removed. As a result, an air gap AG may be formed on each of the common source lines 11s in the main cell region A. The air gap AG may be covered with the capping insulation layer 17 as shown in FIGS. 6A and 6C. When the insulating spacers 15s′ 15s″, 15d′, and 15d″ are formed of a silicon nitride layer, the source-side spacers 15s′ and 15s″ may be selectively removed using phosphoric acid H₃PO₄.

In some embodiments according to the inventive concept, at least a portion of the air gap AG may be formed between the floating gates FG of the second gate pattern GP2 and the floating gates FG of the third gate pattern GP3. Accordingly, the air gap AG may reduce parasitic coupling capacitance C between the floating gates FG of the second gate pattern GP2 and the floating gates FG of the third gate pattern GP3. That is, prior to formation of the air gap AG, the parasitic coupling capacitance C may be affected by the main source-side spacers 15s′ having a higher dielectric constant than air. However, if the air gap AG is formed by removing the main source-side spacers 15s′, the parasitic coupling capacitance C may be affected by air having a lower dielectric constant than the main source-side spacers 15s′. Accordingly, the air gap AG may reduce the parasitic coupling capacitance C between the adjacent floating gates FG of the second and third gate patterns GP2 and GP3.

If the parasitic coupling capacitance C reduces, as mentioned above, electric potential variation of the floating gate FG of a first memory cell adjacent to a second memory cell may be minimized even though the second memory cell is programmed to change an electric potential of the floating gate FG of the second memory cell. Accordingly, it may reduce the likelihood of read errors from occurring in an operation mode for reading out data stored in the first memory cell.

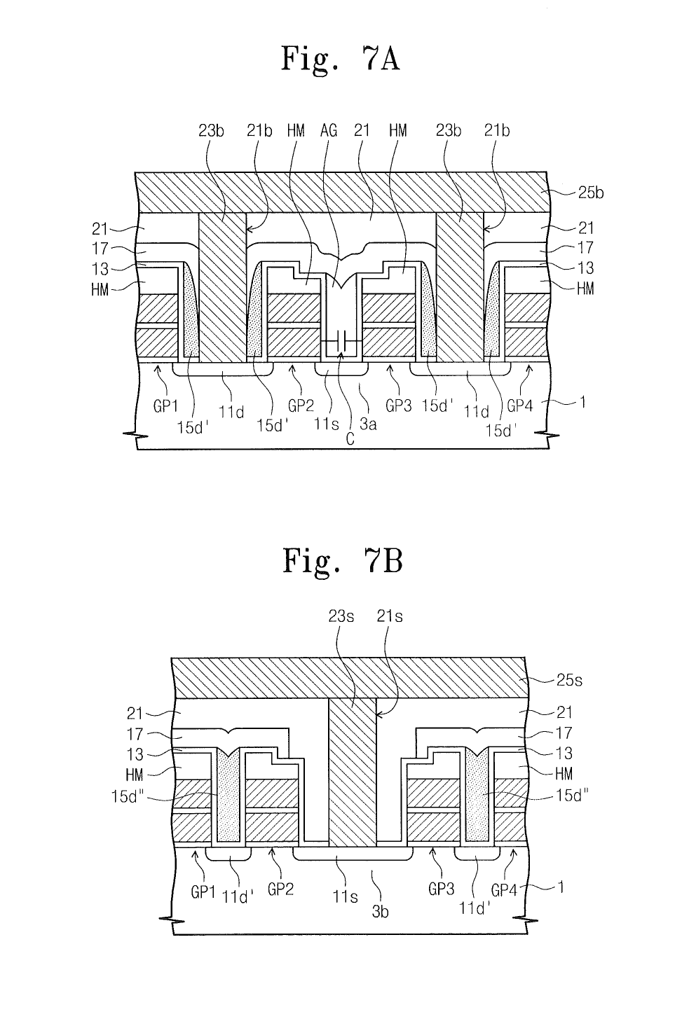

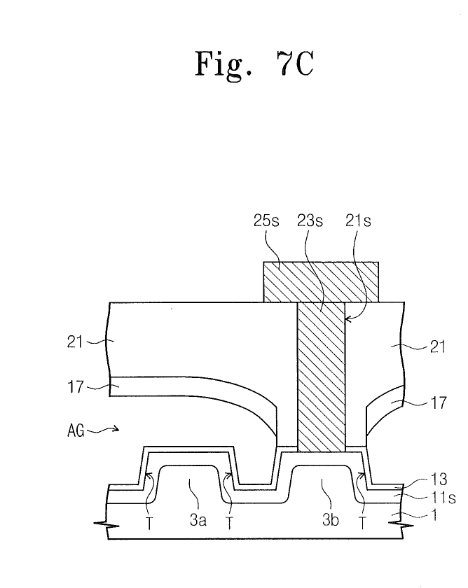

Referring to FIGS. 1, 7A, 7B, and 7C, an interlayer insulation layer 21 is formed on the substrate having the air gap AG. The interlayer insulation layer 21, the capping insulation layer 17 and the first insulation layer 13 may be patterned to form bit line contact holes 21b exposing the main drain regions 11d. During formation of the bit line contact holes 21b, source contact holes 21s may also be formed to expose the common source lines 11s in the dummy active regions 3b. During formation of the contact holes 21b and 21s, the main drain-side spacers 15d′ may serve as an etch stop layer.

Bit line contact plugs 23b and source contact plugs 23s may be formed in the bit line contact holes 21b and the source contact holes 21s, respectively. A conductive layer may be formed on the substrate having the contact plugs 23b and 23s, and the conductive layer may be patterned to form bit lines 25b and source interconnections 25s crossing over the gate patterns GP1, GP2, GP3, and GP4. Each of the bit lines 25b may be electrically connected to the bit line contact plugs 23b on one of the main active regions 3a, and each of the source interconnections 25s may be electrically connected to the source contact plugs 23s on one of the dummy active regions 3b. That is, the bit lines 25b may be formed on the main active regions 3a, respectively, and the source interconnections 25s may be formed on the dummy active regions 3b, respectively.

As mentioned above, the bit line contact plugs 23b are formed on the drain regions 11d, respectively. That is, the bit line contact plugs 23b are formed between the first and second gate patterns GP1 and GP2 and between the third and fourth gate patterns GP3 and GP4. Accordingly, parasitic capacitances between the floating gates FG of the first gate pattern GP1 and the floating gates FG of the second gate patterns GP2 may be too low to affect the read operation of the non-volatile memory device. This is because the bit line contact plugs 23b may shield electric fields between the floating gates FG of the first gate pattern GP1 and the floating gates FG of the second gate patterns GP2. Similarly, parasitic capacitances between the floating gates FG of the third gate pattern GP3 and the floating gates FG of the fourth gate patterns GP4 may be too low to affect the read operation of the non-volatile memory device. As a result, even if no air gap is formed between the first and second gate patterns GP1 and GP2 and between the third and fourth gate patterns GP3 and GP4, a semiconductor device according to embodiments of the inventive concept may operate normally.

Referring to FIGS. 7A, 7B, and 7C, a device isolation layer 3 is disposed in a predetermined region of a semiconductor substrate 1 to define active regions. The active regions may include main active regions 3a in a main cell region A and dummy active regions 3b in a dummy cell region B.

A plurality of gate patterns may be disposed to cross over the main active regions 3a, the dummy active regions 3b, and the device isolation layer 3 therebetween. The plurality of gate patterns may include first to fourth gate patterns GP1, GP2, GP3, and GP4, for example. Each of the gate patterns GP1, GP2, GP3, and GP4 may include a tunnel insulation layer 5, a floating gate FG, an inter-gate insulation layer 7, and a word line WL, which are sequentially stacked. The word line WL may correspond to a control gate electrode.

An interval between the gate patterns GP1, GP2, GP3, and GP4 may vary according to a position as described with reference to FIGS. 1, 2A, and 2B. That is, intervals between the gate patterns GP1, GP2, GP3, and GP4 may include the first to fourth intervals S1, S2, S3, and S4 as shown in FIGS. 1, 2A and 2B.

A line-shaped impurity region, i.e., a common source line 11s, may be disposed in the semiconductor substrate 1 below a space between the second and third gate patterns GP2 and GP3. Additionally, first main drain regions 11d may be formed in the main active regions 3a located adjacent to the second gate pattern GP2 and located distal from the third gate pattern GP3. Similarly, second main drain regions 11d may be formed in the main active regions 3a located adjacent to the third gate pattern GP3 and located distal from the second gate pattern GP2. The common source line 11s may extend into the dummy active region 3b between the second and third gate patterns GP2 and GP3.

Hard masks HM may be stacked on the top surfaces of the gate patterns GP1, GP2, GP3, and GP4. A first insulation layer 13 may be conformally disposed on the substrate having the hard masks HM and the gate patterns GP1, GP2, GP3, and GP4. The first insulation layer 13 may be a CVD oxide layer or a thermal oxide layer.

A capping insulation layer 17 is stacked on the first insulation layer 13, and the capping insulation layer 17 defines an empty space bounded on a lower side by the common source line 11s. That is, an air gap AG covered by the capping insulation layer 17 may be provided between the second and third gate patterns GP2 and GP3.

The second gate pattern GP2 includes a first sidewall adjacent to the common source line 11s and a second sidewall adjacent to the first main drain regions 11d, and the third gate pattern GP3 includes a first sidewall adjacent to the common source line 11s and a second sidewall adjacent to the second main drain regions 11d. Furthermore, the first gate pattern GP1 includes a second sidewall adjacent to the first main drain regions 11d and the fourth gate pattern GP4 includes a second sidewall adjacent to the second main drain regions 11d.

Insulating drain-side spacers 15d′ may be disposed on the second sidewalls of the first, second, third, and fourth gate patterns GP1, GP2, GP3, and GP4. The insulating drain-side spacers 15d′ may be a material layer having an etch selectivity with respect to the capping insulating layer 17. For example, if the capping insulation layer 17 is a silicon oxide layer, the insulating drain-side spacers 15d′ may be a silicon nitride layer.

The capping insulating layer 17 covers the insulating drain-side spacers 15d′ and the drain regions 11d. The capping insulating layer 17 may not provide any air gap between the drain regions 11d and the capping insulation layer 17.

An interlayer insulation layer 21 may be stacked on the capping insulation layer 17. A plurality of bit lines 25b and a plurality of source interconnections 25s crossing over the gate patterns GP1, GP2, GP3, and GP4 may be disposed on the interlayer insulation layer 21. Each of the bit lines 25b may be electrically connected to the drain regions 11d formed in one of the main active regions 3a. Additionally, each of the source interconnections 25s may be electrically connected to the common source lines 11s formed in one of the dummy active regions 3b. That is, the bit lines 25b may be disposed on the main active regions 3a, respectively, and the source interconnections 25s may be disposed on the dummy active regions 3b, respectively.

According to the above-mentioned embodiments of the inventive concept, an air gap is formed between a pair of adjacent gate patterns, and a line-shaped impurity region, i.e., a common source line 11s, is formed in the semiconductor substrate below the air gap. Accordingly, a parasitic coupling capacitance between the pair of gate patterns may be remarkably reduced. Especially, in the case that each of the gate patterns corresponds to a flash memory gate pattern including a sequentially-stacked floating gate and control gate electrode, a parasitic coupling capacitance between adjacent floating gates may be significantly reduced due to the air gap.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1.-6. (canceled)

7. A semiconductor device comprising:
a device isolation layer on a semiconductor substrate to define a plurality of main active regions;
first and second gate patterns crossing over the main active regions and the device isolation layer therebetween;
a common source line in the semiconductor substrate between the first and second gate patterns;
a capping insulation layer covering an air gap between the first and second gate patterns;
a plurality of first drain regions in the main active regions located immediately adjacent to the first gate pattern and located distal from the second gate pattern, respectively; and
a plurality of second drain regions in the main active regions located immediately adjacent to the second gate pattern and located distal from the first gate pattern, respectively.

8. The semiconductor device of claim 7, wherein the first gate pattern comprises a first sidewall adjacent to the common source line and a second sidewall immediately adjacent to the first drain regions and the second gate pattern comprises a first sidewall adjacent to the common source line and a second sidewall adjacent to the second drain regions.

9. The semiconductor device of claim 8, further comprising:
an insulating spacer on the second sidewalls of the first and second gate patterns, wherein the capping insulation layer comprises a material layer having an etch selectivity with respect to the insulating spacer.

10. The semiconductor device of claim 7, wherein the capping insulation layer extends to cover the first and second drain regions, and the capping insulation layer provides no air gap between the capping insulation layer and the drain regions.

11. The semiconductor device of claim 7, further comprising:
an interlayer insulation layer on the capping insulation layer; and
bit lines on the interlayer insulation layer,
wherein each of the bit lines is electrically connected to the first and second drain regions formed in one of the main active regions.

12. The semiconductor device of claim 7, further comprising at least one dummy active region defined by the device isolation layer and disposed adjacent to the main active regions,
wherein the first and second gate patterns extend to cross over the dummy active region.

13. The semiconductor device of claim 12, wherein a first interval between the first and second gate patterns crossing over the main active regions is less than a second interval between the first and second gate patterns crossing over the dummy active region.

14. The semiconductor device of claim 13, further comprising:
an interlayer insulation layer on the capping insulation layer; and
at least one source interconnection disposed on the interlayer insulation layer,
wherein the source interconnection is electrically connected to the common source line.

15. A non-volatile semiconductor memory device comprising:
immediately adjacent floating gates spaced apart by a gap on a semiconductor substrate in a main memory region of the device;
a capping insulating layer, above the substrate, bridging the gap; and
a common source line in the semiconductor substrate shared by the immediately adjacent floating gates.

16. The device according to claim 15 wherein the capping insulating layer extends over the immediately adjacent floating gates and onto sidewalls thereof in the main memory region of the device over immediately adjacent drain regions in the semiconductor substrate.

17. The device according to claim 16 further comprising:
a bit line in the main memory region of the device penetrating the capping insulating layer to electrically connect to one of the immediately adjacent drain regions.

18. The device according to claim 17 wherein the gap comprises a first distance, the device further comprising:
a dummy floating gate, in a dummy region of the device, spaced apart from a closest one of the immediately adjacent floating gates by a second distance that is greater than the first distance.

19. The device according to claim 18 wherein the second distance is greater than the first distance.

20. The device according to claim 18 wherein the second distance between the dummy floating gate and the closest one of the immediately adjacent floating gates is free of the gap.
